(19) United States
(12) Patent Application Publication
(10) Pub. No.: US 2008/0213677 A1
(43) Pub. Date: Sep. 4, 2008

(54) PHOTOMASK MANUFACTURING METHOD USING CHARGED BEAM WRITING APPARATUS

(76) Inventor: Masato Saito, Machida-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/015,032

(22) Filed: Jan. 16, 2008

(30) Foreign Application Priority Data
Jan. 17, 2007 (JP) 2007-008085

(51) Int. Cl. G03F 1/00; G03F 7/00

(52) U.S. Cl. 430/5; 430/319

(57) ABSTRACT

A first relationship between the charge dose of a charged beam writing apparatus and the dimensional accuracy of a photomask pattern is obtained, and a charge dose is determined from given dimensional accuracy on the basis of the first relationship. On the basis of the determined charge dose, a resist by which a resist pattern having desired dimensions is formed with the charge dose is selected. A second relationship between the write condition of the charged beam writing apparatus and the write time necessary to write the selected resist with the charge dose is obtained for each write pattern. The write condition is determined for each write pattern on the basis of a condition given to the write time and the second relationship.

### CROSS-REFERENCE TO RELATED APPLICATIONS

This application is based upon and claims the benefit of priority from prior Japanese Patent Application No. 2007-008085, filed Jan. 17, 2007, the entire contents of which are incorporated herein by reference.

### BACKGROUND OF THE INVENTION

1. Field of the Invention

The present invention relates to a photomask manufacturing method using a charged beam writing apparatus, and a semiconductor device fabrication method using the photomask.

2. Description of the Related Art

To form a semiconductor circuit pattern on a photomask substrate for use in the fabrication of a semiconductor element, a method is widely used by which a photosensitive agent supplied on a substrate by coating is exposed by using a charged beam writing apparatus, particularly, an electron beam writing apparatus, and processes such as development and etching are performed on the exposed substrate, thereby forming a desired circuit pattern on the substrate.

One accuracy required of the manufactured photomask is the local critical dimension (CD) accuracy as the dimensional accuracy within a narrow range that is not affected by the processes such as development and etching. The local CD accuracy is the dimensional accuracy reproducibility in a narrow region that is not influenced by the instability of the process. The cause of deterioration of the local CD accuracy has been regarded as pattern edge roughness resulting from, e.g., a beam blur or a beam irradiation position error of a writing apparatus, so the local CD accuracy has been increased by improving the writing apparatus. As the improvement in performance of the writing apparatus advances, however, deterioration of the pattern edge roughness caused by factors other than the writing apparatus is beginning to be observed.

One cause of deterioration of the local CD accuracy is a phenomenon called shot noise. In this phenomenon, the irradiation positions of individual charged particles emitted as a charged beam are probabilistically unevenly distributed, thereby producing roughness in the pattern edge portion. When measurement is performed by a region of interest (ROI) having a finite width, therefore, the detected CD accuracy is limited.

It is reported that when an electron beam writing apparatus is used with a generally used chemical amplification type resist, the limit of the local CD accuracy is determined by the acid diffusion diameter of the resist used, the beam resolution, the number of incident electrons (the charge dose), and the measurement ROI width (e.g., Ming L. Yu, et al., Exploring the fundamental limit of CD control: shot noise and CD uniformity improvement through resist thickness”, Proceedings of SPIE Vol. 5853, p. 42-51).

As the degree of micropatterning and the accuracy of semiconductor devices increase, the accuracy required of the photomask is becoming stricter and approaching the above-mentioned limit. To achieve the required accuracy, therefore, there is no method except for reducing the deterioration component of the local CD accuracy resulting from shot noise. To improve the deterioration of the local CD accuracy caused by shot noise particularly in the state in which the improvement of the writing apparatus has advanced and the beam resolution has well increased, it is essential to increase the number of incident electrons necessary to form a desired pattern by decreasing the sensitivity of a resist, or decrease the acid diffusion diameter of the resist.

The sensitivity of a resist can be relatively easily adjusted by adjusting the ratio of components forming the resist. Therefore, decreasing the sensitivity of a resist is presumably the most efficient method that increases the local CD accuracy.

It is possible by using a plurality of resists different in sensitivity to experimentally obtain the local CD accuracy that is to be obtained when a charge dose required to form desired pattern dimensions is changed.

Consequently, the reciprocal (i.e., D^{-1/2}) of the square root of a charge dose D and the local CD accuracy are found to have a proportional relationship as predicted from the result disclosed in the above-mentioned thesis; as the charge dose D increases (and the resist sensitivity decreases at the same time), the local CD accuracy increases.

As described above, it is effective to decrease the sensitivity of a resist and increase the charge dose in order to increase the local CD accuracy. When the charge dose increases, however, the electron beam emission time increases during writing, and this decreases the write throughput.

To solve this problem, it is possible to raise the current density of a writing apparatus and increase the charge dose that can be emitted within a predetermined time, thereby suppressing the decrease in throughput caused by the decrease in sensitivity of a resist. In this case, however, the accuracy probably decreases due to the spatial charge effect (the decrease in beam resolution), or the influence of resist heating (the change in chemical composition by heat).

Accordingly, it is necessary to decrease the maximum shot size or increase the write multiplicity when a variable shaped beam method is used, and it is necessary to delay the shot cycle even when a raster beam method is used. Unfortunately, the write time increases in either case.

### BRIEF SUMMARY OF THE INVENTION

A photomask manufacturing method according to the first aspect of the present invention, there is provided a photomask manufacturing method of forming a photomask having a desired pattern by irradiating a resist formed on a photomask material by coating with a charged beam by using a charged beam writing apparatus, the method comprising obtaining a first relationship between a charge dose and dimensional accuracy of a photomask pattern, determining a charge dose from given dimensional accuracy on the basis of the first relationship, selecting, on the basis of the determined charge dose, a resist by which a resist pattern having a desired dimension is formed with the charge dose, obtaining, for each write pattern, a second relationship between a write condition of the charged beam writing apparatus and a write time necessary to write the selected resist with the charge dose, and determining the write condition for each write pattern on the basis of a condition given to the write time and the second relationship.

A photomask manufacturing method according to the second aspect of the present invention, there is provided a photomask manufacturing method of forming a photomask having a desired pattern by irradiating a resist formed on a photomask material by coating with a charged beam by using a charged beam writing apparatus, the method comprising, obtaining a first relationship between a ratio of a charge dose to an acid diffusion diameter in a resist and dimensional accuracy of a photomask pattern, determining a ratio of a charge dose to an acid diffusion diameter in a resist from given dimensional accuracy on the basis of the first relationship, selecting, on the basis of a charge dose and an acid diffusion diameter which satisfy the determined ratio, a resist by which a resist pattern having a desired dimension is formed with the charge dose, and which has the acid diffusion diameter, obtaining, for each write pattern, a second relationship between a write condition of the charged beam writing apparatus and a write time necessary to write the selected resist with the charge dose, and determining the write condition for each write pattern on the basis of a condition given to the write time and the second relationship.

A semiconductor device fabrication method according to the third aspect of the present invention, there is provided a semiconductor device fabrication method comprising forming a photomask having a desired pattern by irradiating a resist formed on a photomask material by coating with a charged beam by using a charged beam writing apparatus, and etching an object to be processed by using the formed photomask, wherein forming the photomask includes, selecting a resist from a plurality of resists on the basis of a first relationship, obtaining, for each write pattern, a second relationship between a write condition of the charged beam write apparatus and a write time necessary to write the selected resist with a charge dose, and determining the write condition for each write pattern on the basis of a condition given to the write time and the second relationship.

### BRIEF DESCRIPTION OF THE SEVERAL VIEWS OF THE DRAWING

FIG. 1 is a diagram for explaining a photomask manufacturing method according to the first embodiment of the present invention, in which the relationship between the charge dose and the local CD accuracy is shown;

FIG. 2 is a diagram for explaining the photomask manufacturing method according to the first embodiment of the present invention, in which the relationship between the current density and the maximum shot size is shown;

FIG. 3 is a diagram showing the relationship between the maximum shot size and the number of shots necessary to form a given pattern;

FIG. 4 is a diagram showing the relationship between the current density and the write time for each pattern;

FIG. 5 is a diagram showing a current density range satisfying a given write time condition for each pattern;

FIG. 6 is a flowchart showing the photomask manufacturing method according to the first embodiment of the present invention;

FIG. 7 is a diagram for explaining a photomask manufacturing method according to the second embodiment of the present invention, in which the relationship between the ratio of the charge dose to the acid diffusion diameter and the local CD accuracy is shown;

FIG. 8 is a diagram for explaining the photomask manufacturing method according to the second embodiment of the present invention, in which the relationship between the current density and the maximum shot size is shown; and

FIG. 9 is a flowchart showing the photomask manufacturing method according to the second embodiment of the present invention.

### DETAILED DESCRIPTION OF THE INVENTION

### First Embodiment

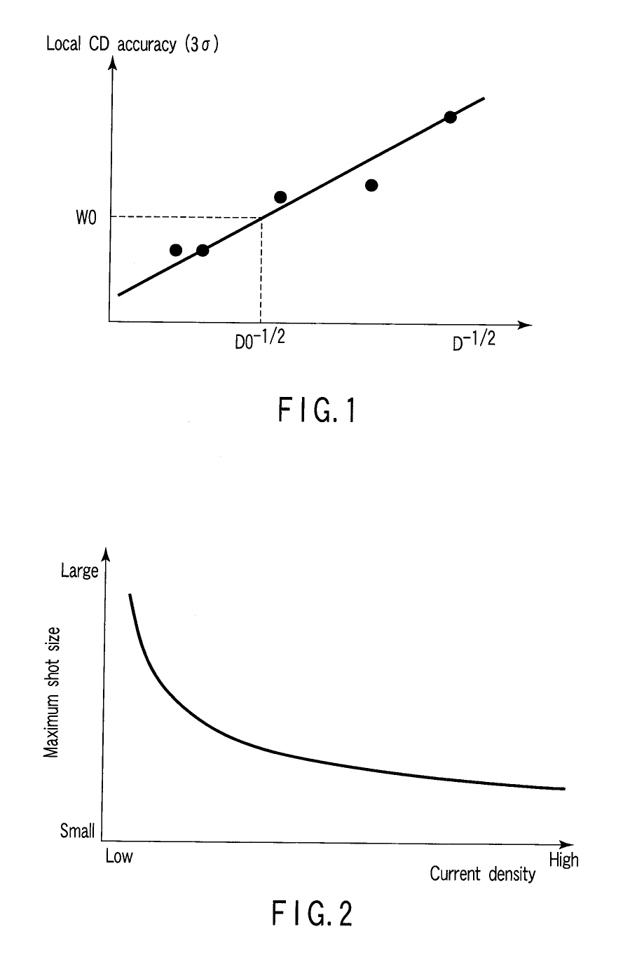

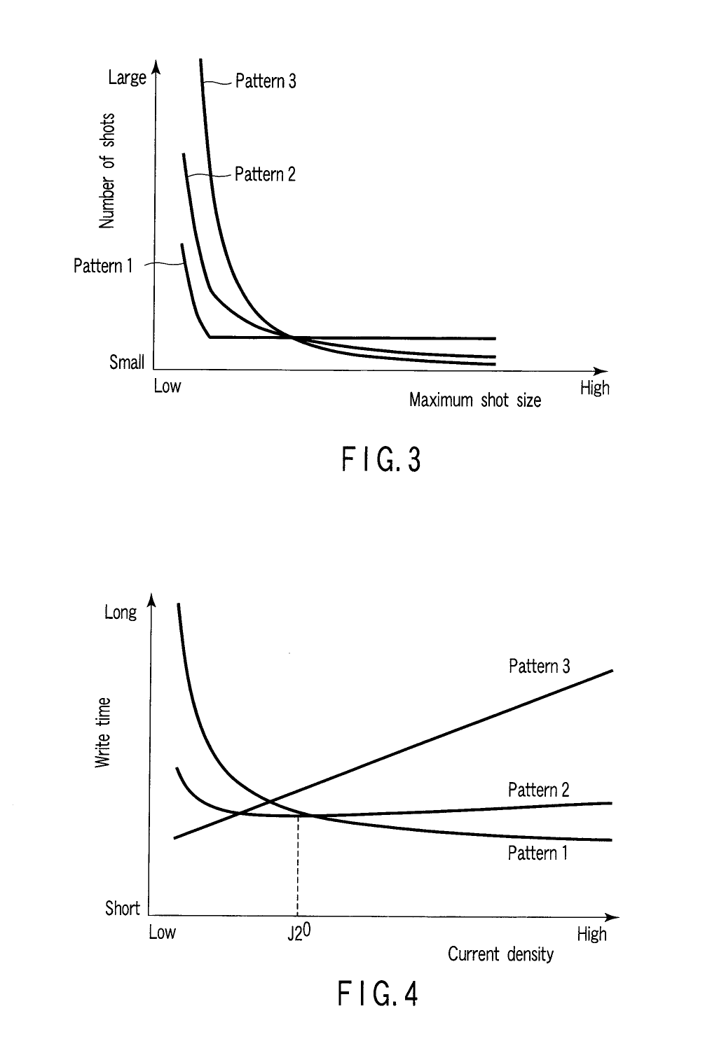

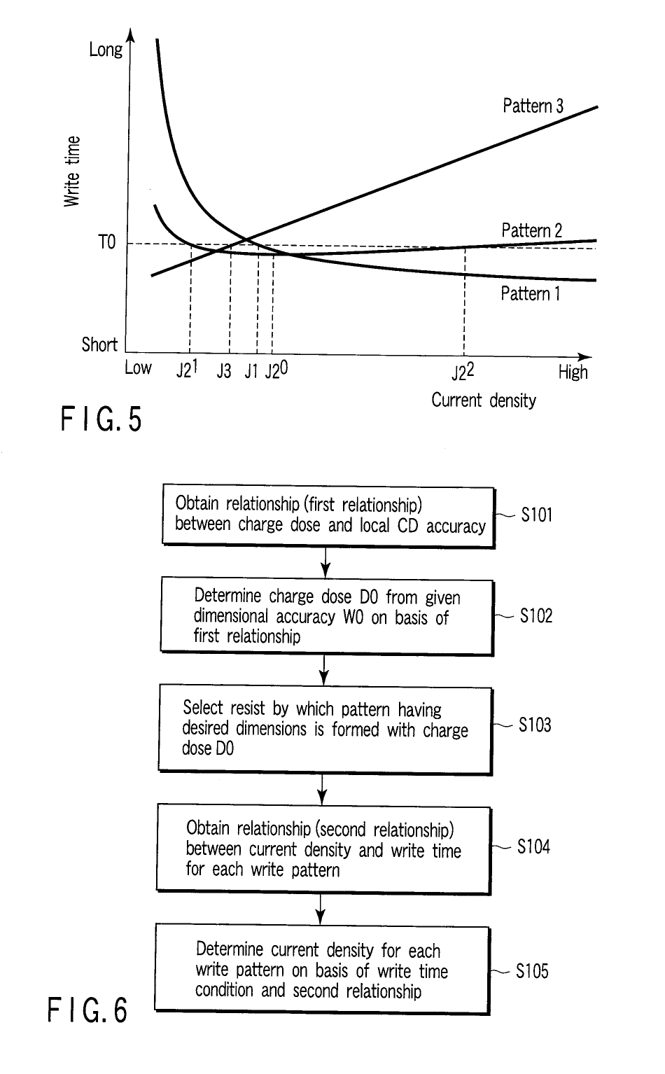

A photomask manufacturing method according to the first embodiment of the present invention will be explained below with reference to FIGS. 1 to 6. FIG. 1 is a diagram showing the relationship between the charge dose and the local CD accuracy. FIG. 2 is a diagram showing the relationship between the current density and the maximum shot size. FIG. 3 is a diagram showing the relationship between the maximum shot size and the number of shots necessary to form a given pattern. FIG. 4 is a diagram showing the relationship between the current density and the drawing time for each pattern. FIG. 5 is a diagram showing a current density range satisfying a given drawing time condition for each pattern. FIG. 6 is a flowchart showing the photomask manufacturing method.

In the first embodiment, the relationship between the charge dose and the dimensional accuracy of a photomask pattern is obtained beforehand, and an appropriate charge dose is determined from the dimensional accuracy of a given mask pattern on the basis of the relationship.

In the general photomask manufacture, a light-shielding film made of Cr or the like is formed on the surface of a quartz mask blank. A pattern is written by a charged beam on a resist formed on the light-shielding film by coating, and the desired pattern is formed on the light-shielding film through processes such as development and etching.

The photomask manufacturing method according to the first embodiment uses a variable shaped beam type electron beam writing apparatus. First, as shown in the flowchart of FIG. 6, a plurality of resists different in sensitivity are prepared, and the local CD accuracy to be obtained when a charge dose D necessary to form desired pattern dimensions is changed is experimentally obtained (step S101).

The charge dose D is a charge amount emitted per unit area. The sensitivity of a resist is defined by the charge dose D required to form a resist pattern having desired dimensions after processes such as development. The local CD accuracy is the dimensional accuracy required of a photomask within a narrow range that is not affected by processes such as development and etching. This embodiment uses 3σ as the triple of a CD standard deviation σ indicating the variation in CD.

In the first embodiment, a plurality of resists different in sensitivity are prepared so as to select a resist having sensitivity necessary and sufficient to form desired pattern dimensions. These resists can be different in contents of component materials or different in component materials themselves.

FIG. 1 is a diagram showing the relationship (first relationship) between the local CD accuracy (3σ) obtained by the experiment described above and the charge dose D. FIG. 1 shows that the reciprocal (i.e., D^{-1/2}) of the square root of the charge dose D and the local CD accuracy (3σ) are almost proportional.

When the local CD accuracy required of a photomask to be manufactured is W₀ in FIG. 1, therefore, a resist charge dose necessary and sufficient to achieve this accuracy is D₀, so it is determined that the charge dose is D₀ (step S102). Accordingly, a resist having sensitivity by which desired pattern dimensions are formed with the charge dose D₀ is selected (step S103).

Note that the first embodiment uses the relationship between the local CD accuracy and the charge dose experimentally obtained in advance. However, it is also possible to use data based on theoretical prediction, or data obtained by performing mathematical processing on experimentally obtained data.

Then, write conditions optimum when the selected resist is used are determined for each pattern to be written.

Generally, when the current density as one write condition of a writing apparatus increases, the write time shortens because the charge amount that can be emitted within a unit time increases. When the current density changes, however, the beam resolution, i.e., a beam blur amount R changes due to the spatial charge effect. The beam blur amount R is proportional to a current within one shot, and the current within one shot is the product of the maximum shot size (sectional area) and the current density.

To maintain the accuracy (beam resolution), therefore, the maximum shot size must be limited so that the current within one shot is equal to or smaller than a prescribed value. Accordingly, as shown in FIG. 2, the maximum shot size often decreases when the current density increases.

When the maximum shot size decreases, the write time prolongs because the number of shots necessary to form the same pattern increases. FIG. 3 shows the relationship between the maximum shot size and the number of shots necessary to form a given pattern.

As shown in FIG. 3, the way the number of shots increases changes from one pattern type to another. For example, when the size of a figure included in a pattern is much smaller than the maximum shot size, the number of shots does not increase even if the maximum shot size decreases (pattern 1). If the maximum shot size extremely decreases, however, the number of shots naturally increases regardless of the pattern type.

On the other hand, when the size of a figure included in a pattern is much larger than the maximum shot size, the number of shots increases inversely proportional to the maximum shot size area (the square of the maximum shot size) (pattern 3). Pattern 2 is intermediate between patterns 1 and 3. An example of pattern 2 is the case where the number of shots increases in inverse proportion to the maximum shot size.

The relationship between the current density and the number of shots can be derived from the relationship between the maximum shot size and the number of shots shown in FIG. 3, and the relationship between the current density and the maximum shot size shown in FIG. 2. In addition, the write time of each pattern can be expressed by

$$\begin{matrix}Write time = time required for one shot \times number of shots \\ = ( beam emission time + settling time ) \times \\ number of shots\end{matrix} \qquad ( 1 )$$

The time required for one shot can be expressed by the sum of the beam emission time and settling time. The beam emission time is a time during which the beam is actually emitted, and is a time required to emit the charge dose determined in step S102 by a given current density. The beam emission time is inversely proportional to the current density. The (shot) settling time is an offset time necessary for an preparing operation for emitting the beam for each shot, and has a fixed value. Furthermore, the number of shots generally increases when it is necessary to perform a shot by changing the position in order to write a given pattern. However, the number of shots also increases when writing a pattern with a given write multiplicity, e.g., when performing two-shot writing in the same position by halving the beam emission time.

The write time at a specific current density can be calculated for each pattern by calculating the time required for one shot when writing is performed at the current density, and multiplying the time by the number of shots in accordance with equation 1. As shown in FIG. 4, therefore, the relationship (second relationship) between the current density and the write time can be obtained for each pattern from the relationship between the current density and the number of shots derived as described above and equation 1 (step S104).

As shown in FIG. 4, there are three cases in accordance with patterns to be written: the case (pattern 1) where the write time can be shortened as the current density increases; the case (pattern 2) where the current density value that minimizes the write time exists; and the case (pattern 3) where the write time prolongs as the current density increases.

On the basis of the relationships shown in FIG. 4, therefore, the current density is set as high as possible as the performance of the writing apparatus in the case of pattern 1, is set at J₂⁰ as a current density capable of minimizing the write time in the case of pattern 2, and is set as low as possible as the performance of the writing apparatus in the case of pattern 3. This makes it possible to perform optimization so as to minimize the total write time of patterns.

Also, if it is necessary to set the write time of each pattern to T₀ or less, for example, as shown in FIG. 5, it is also possible to set the current density at J₁ or more in the case of pattern 1, between J₂¹ and J₂² in the case of pattern 2, and at J₃ or less in the case of pattern 3 (step S105).

In the first embodiment, a resist that satisfies the dimensional accuracy of a required photomask pattern and has sensitivity necessary and sufficient to form a resist pattern having desired dimensions is selected. In addition, write conditions having the highest productivity are calculated from the relationship between the write conditions of a charged beam writing apparatus and the write throughput, for each pattern to be written in the selected resist. This makes it possible to minimize or optimize the write time. Accordingly, the productivity of a semiconductor device can be increased by manufacturing a photomask by the photomask manufacturing method according to the first embodiment, and fabricating the semiconductor device by using the photomask.

Note that in the first embodiment, the write time is calculated by taking account of the current density, settling time, write multiplicity, and the like. However, it is also possible to calculate the write time by including a parameter, such as the periodical adjusting time of a writing apparatus, which contributes to the write time. Note also that the first embodiment has disclosed the method of calculating the optimum current density for each individual pattern. However, the current density may also be set for average data of a plurality of patterns on the basis of parameters such as the pattern coverage and minimum dimension.

Furthermore, the first embodiment has been explained by taking the current density as an example of the write condition, which is to be optimized with respect to the write time, of a charged beam writing apparatus. However, the maximum shot size may also be used as the write condition to be optimized by using the relationship shown in FIG. 2. It is also possible to use the write multiplicity or the like as the write condition to be optimized with respect to the write time, while fixing other write conditions.

### Second Embodiment

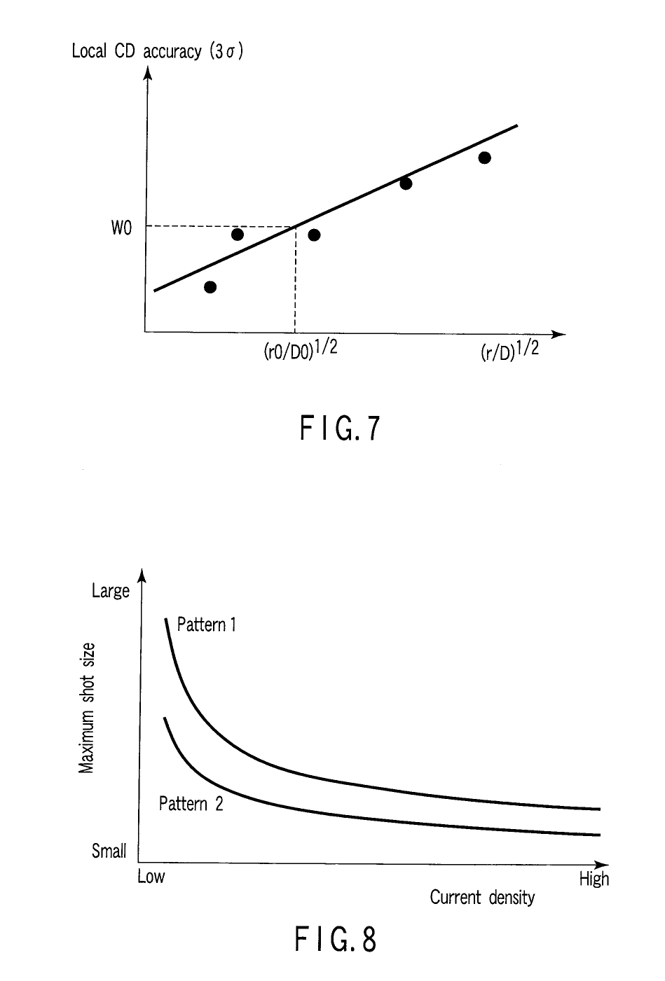

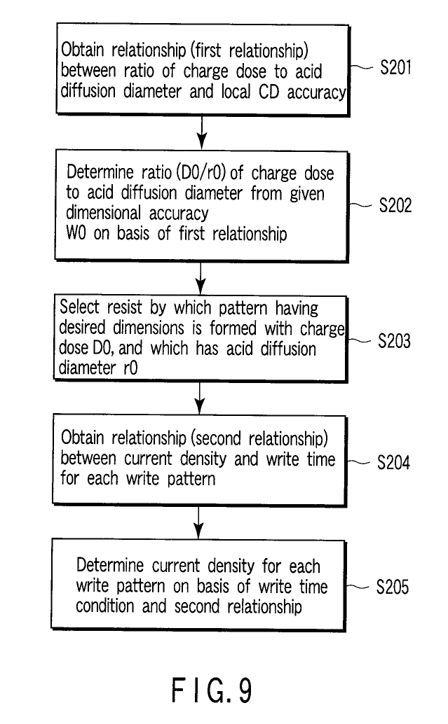

A photomask manufacturing method according to the second embodiment of the present invention will be explained below with reference to FIGS. 7 to 9. FIG. 7 is a diagram showing the relationship between the ratio of the charge dose to the acid diffusion diameter and the local CD accuracy. FIG. 8 is a diagram showing the relationship between the current density and the maximum shot size. FIG. 9 is a flowchart showing the photomask manufacturing method.

The second embodiment takes account of not only the sensitivity but also the diffusion diameter of an acid in a resist to be used as the characteristics of the resist. That is, the relationship between the ratio of the charge dose to the acid diffusion diameter in a resist and the dimensional accuracy of a photomask pattern is obtained beforehand. On the basis of this relationship, an appropriate ratio of the charge dose to the acid diffusion diameter in the resist is determined from the dimensional accuracy of a given mask pattern.

The thesis described earlier has reported that when the beam resolution of a writing apparatus is much smaller than the acid diffusion diameter in a resist, the local CD accuracy (3σ) resulting from shot noise is proportional to the square root of an acid diffusion diameter r as well. Also, as described previously, the local CD accuracy is proportional to the reciprocal (i.e., D^{-1/2}) of the square root of the charge dose D. When the relationship (first relationship) between the local CD accuracy and the ratio of the charge dose to the acid diffusion diameter is actually obtained by an experiment (step S201 in FIG. 9), the local CD accuracy is proportional to the square root of (r/D) as indicated by the graph shown in FIG. 7.

Accordingly, when the local CD accuracy required of a photomask to be manufactured is W₀ in FIG. 7, the ratio of the charge dose D to the acid diffusion diameter r necessary and sufficient to achieve this accuracy is determined (step S202). Referring to FIG. 7, a relationship satisfying the ratio is that the charge dose to a resist is D₀, and the acid diffusion diameter in the resist is r₀. Therefore, a resist which has the acid diffusion diameter r₀ and by which desired pattern dimensions are formed with the charge dose D₀ is selected (step S203).

Note that the second embodiment uses the relationship between the local CD accuracy and the ratio of the charge dose to the acid diffusion diameter experimentally obtained in advance. However, it is also possible to use data based on theoretical prediction, or data obtained by performing mathematical processing on experimentally obtained data.

Then, write conditions optimum when the selected resist is used are determined for each pattern to be written in the same manner as in the first embodiment.

In this case, the beam resolution, i.e., a beam blur amount R resulting from the spatial charge effect must be much smaller than the acid diffusion diameter in a resist to be used. Therefore, the allowable width of the maximum shot size exists in accordance with the acid diffusion diameter. FIG. 8 shows the relationship between the current density and the maximum shot size when the allowable value of the beam blur amount is changed in accordance with the acid diffusion diameter. As described in the first embodiment, the beam blur amount R is proportional to a current within one shot, and the current within one shot is the product of the maximum shot size (sectional area) and the current density.

Pattern 1 in FIG. 8 is an example in which a resist having a large acid diffusion diameter is selected. In this case, the beam blur amount R, i.e., the product of the maximum shot size (sectional area) and the current density can be large in accordance with the acid diffusion diameter. Therefore, the maximum shot size can be increased even when the current density rises.

On the other hand, pattern 2 is an example in which a resist having a small acid diffusion diameter is selected. Since the beam blur amount R must be decreased, the maximum shot size that can be used is smaller than that in pattern 1.

As shown in FIG. 8, the relationship between the current density and the maximum shot size is obtained in accordance with the resist selected in step S203. Therefore, the relationship (second relationship) between the current density and the write time can be obtained for each pattern as shown in FIG. 4 from the above relationship, the relationship between the maximum shot size and the number of shots required to form a given pattern shown in FIG. 3, and equation 1 (step S204).

On the basis of the relationship between the current density and the write time of each pattern obtained in step S204, a current density that minimizes the write time can be selected for each pattern in the same manner as in the first embodiment. This makes it possible to perform optimization so as to minimize the total write time of patterns.

Also, as in the first embodiment, if it is necessary to set the write time of each pattern to T₀ or less, for example, as shown in FIG. 5, it is possible to set the current density at J₁ or more in the case of pattern 1, between J₂¹ and J₂² in the case of pattern 2, and at J₃ or less in the case of pattern 3 (step S205).

In the second embodiment, the relationship between the ratio of the charge dose to the acid diffusion diameter in a resist and the dimensional accuracy of a photomask pattern is obtained beforehand, and, on the basis of this relationship, an appropriate ratio of the charge dose to the acid diffusion diameter in a resist is determined from the dimensional accuracy of a given mask pattern. In this way, a resist which satisfies the dimensional accuracy of the required photomask pattern and by which a resist pattern having desired dimensions is formed is selected. In addition, write conditions having the highest productivity are calculated for each pattern to be written in the selected resist from the relationship between the write conditions of a charged beam writing apparatus and the write throughput. This makes it possible to minimize or optimize the write time. Accordingly, the productivity of a semiconductor device can be increased by manufacturing a photomask by the photomask manufacturing method according to the second embodiment, and fabricating the semiconductor device by using the photomask.

Note that the write time may also be calculated by taking account of parameters, such as the write multiplicity and the periodical adjusting time of a writing apparatus, which contribute to the write time, in addition to the current density and settling time, in the second embodiment as well. Note also that the second embodiment has disclosed the method of calculating the optimum current density for each individual pattern, but the current density may also be set for average data of a plurality of patterns on the basis of parameters such as the pattern coverage and minimum dimension.

Furthermore, the second embodiment has been explained by taking the current density as an example of the write condition, which is to be optimized with respect to the write time, of a charged beam writing apparatus. However, the maximum shot size may also be used as the write condition to be optimized by using the relationship shown in FIG. 8. It is also possible to use the write multiplicity or the like as the write condition to be optimized with respect to the write time, while fixing other write conditions.

As described above, according to one aspect of this invention, it is possible to provide a photomask manufacturing method using a charged beam writing apparatus and having high write throughput, and a semiconductor device fabrication method having high productivity.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A photomask manufacturing method of forming a photomask having a desired pattern by irradiating a resist formed on a photomask material by coating with a charged beam by using a charged beam writing apparatus, the method comprising:
obtaining a first relationship between a charge dose and dimensional accuracy of a photomask pattern;
determining a charge dose from given dimensional accuracy on the basis of the first relationship;
selecting, on the basis of the determined charge dose, a resist by which a resist pattern having a desired dimension is formed with the charge dose;
obtaining, for each write pattern, a second relationship between a write condition of the charged beam writing apparatus and a write time necessary to write the selected resist with the charge dose; and
determining the write condition for each write pattern on the basis of a condition given to the write time and the second relationship.

2. A method according to claim 1, wherein selecting the resist comprises selecting, from a plurality of resists different in sensitivity, a resist having sensitivity by which a desired pattern dimension is formed with a charge dose based on local critical dimension accuracy.

3. A method according to claim 1, wherein in determining the write condition, the write condition is determined to minimize a total necessary write time of patterns to be written.

4. A method according to claim 1, wherein in determining the write condition, the write time is calculated by using a plurality of patterns, and the write condition is determined to minimize an average value of the write times of the plurality of patterns.

5. A method according to claim 1, wherein the write time is set to include at least one of a current density, a settling time, a write multiplicity, and a periodical adjusting time of the writing apparatus as a parameter.

6. A method according to claim 1, wherein the write condition includes one of a current density, a maximum shot size, and a write multiplicity.

7. A photomask manufacturing method of forming a photomask having a desired pattern by irradiating a resist formed on a photomask material by coating with a charged beam by using a charged beam writing apparatus, the method comprising:
obtaining a first relationship between a ratio of a charge dose to an acid diffusion diameter in a resist and dimensional accuracy of a photomask pattern;
determining a ratio of a charge dose to an acid diffusion diameter in a resist from given dimensional accuracy on the basis of the first relationship;
selecting, on the basis of a charge dose and an acid diffusion diameter which satisfy the determined ratio, a resist by which a resist pattern having a desired dimension is formed with the charge dose, and which has the acid diffusion diameter;
obtaining, for each write pattern, a second relationship between a write condition of the charged beam writing apparatus and a write time necessary to write the selected resist with the charge dose; and
determining the write condition for each write pattern on the basis of a condition given to the write time and the second relationship.

8. A method according to claim 7, wherein in determining the write condition, the write condition is determined to minimize a total necessary write time of patterns to be written.

9. A method according to claim 7, wherein in determining the write condition, the write time is calculated by using a plurality of patterns, and the write condition is determined to minimize an average value of the write times of the plurality of patterns.

10. A method according to claim 7, wherein the write time is set on the basis of at least one of a current density, a settling time, a write multiplicity, and a periodical adjusting time of the writing apparatus as a parameter.

11. A method according to claim 7, wherein the write condition includes one of a current density, a maximum shot size, and a write multiplicity.

12. A semiconductor device fabrication method comprising:
forming a photomask having a desired pattern by irradiating a resist formed on a photomask material by coating with a charged beam by using a charged beam writing apparatus; and
etching an object to be processed by using the formed photomask,
wherein forming the photomask includes:
selecting a resist from a plurality of resists on the basis of a first relationship;
obtaining, for each write pattern, a second relationship between a write condition of the charged beam write apparatus and a write time necessary to write the selected resist with a charge dose; and
determining the write condition for each write pattern on the basis of a condition given to the write time and the second relationship.

13. A method according to claim 12, wherein selecting the resist on the basis of the first relationship includes:
obtaining the first relationship between a charge dose and dimensional accuracy of a photomask pattern;
determining a charge dose from given dimensional accuracy on the basis of the first relationship; and
selecting, on the basis of the determined charge dose, a resist by which a resist pattern having a desired dimension is formed with the charge dose.

14. A method according to claim 12, wherein selecting the resist on the basis of the first relationship includes:
obtaining the first relationship between a ratio of a charge dose to an acid diffusion diameter in a resist and dimensional accuracy of a photomask pattern;
determining a ratio of a charge dose to an acid diffusion diameter in a resist from given dimensional accuracy on the basis of the first relationship; and
selecting, on the basis of a charge dose and an acid diffusion diameter which satisfy the determined ratio, a resist by which a resist pattern having a desired dimension is formed with the charge dose, and which has the acid diffusion diameter.

15. A method according to claim 12, wherein in determining the write condition, the write condition is determined to minimize a total necessary write time of patterns to be written.

16. A method according to claim 12, wherein the write time is set on the basis of at least one of a current density, a settling time, a write multiplicity, and a periodical adjusting time of the writing apparatus as a parameter.

17. A method according to claim 12, wherein the write condition includes one of a current density, a maximum shot size, and a write multiplicity.
